(19) United States
(12) Patent Application Publication
(10) Pub. No.: US 2026/0100232 A1
(43) Pub. Date: Apr. 9, 2026

(54) HIGH VOLTAGE SWITCH CIRCUITRY AND NON-VOLATILE MEMORY DEVICE INCLUDING THE SAME

(71) Applicant: SAMSUNG ELECTRONICS CO., LTD., SUWON-SI (KR)

(72) Inventor: Tae-Hong KWON, Suwon-si (KR)

(21) Appl. No.: 19/311,140

(22) Filed: Aug. 27, 2025

(30) Foreign Application Priority Data
Oct. 8, 2024 (KR) 10-2024-0136353

(51) Int. Cl. G11C 16/12; G11C 16/30

(52) U.S. Cl. CPC G11C 16/12; G11C 16/30

(57) ABSTRACT

A high voltage switch circuitry of a non-volatile memory device includes a first pass transistor, a depletion mode transistor, a level shifter and a first voltage source. The first pass transistor configured to transfer a driving voltage to an output terminal connected to a second pass transistor of the non-volatile memory device, upon being turned on based on its gate receiving a negative voltage. The depletion mode transistor configured to provide the first pass transistor with the driving voltage based on an output signal fed back from the output terminal. The level shifter applies a voltage to the gate of the first pass transistor. The first voltage source supplies the negative voltage less than the ground voltage to the level shifter. The level shifter is further configured to apply the negative voltage from the first voltage source to the gate of the first pass transistor.

### CROSS-REFERENCE TO RELATED APPLICATION

This U.S. patent application claims priority under 35 U.S. C. § 119 to Korean Patent Application No. 10-2024-0136353, filed in the Korean Intellectual Property Office on Oct. 8, 2024, the disclosure of which is incorporated by reference in its entirety herein.

### TECHNICAL FIELD

The present disclosure is directed to high voltage switch circuitry and a non-volatile memory device including the same.

### DESCRIPTION OF RELATED ART

A semiconductor memory device is an integrated circuit that stores data electronically using semiconductor materials. These devices include volatile types like dynamic-random-access memory (DRAM) and static-random-access-memory (SRAM) and non-volatile types such as flash memory. Volatile semiconductor memory devices offer rapid read/write speeds, but lose their stored data when the power supply is interrupted. On the other hand, non-volatile semiconductor memory devices preserve stored content even when the power supply is interrupted. Therefore, a non-volatile semiconductor memory device such as the flash memory is often selected when content needs to be preserved, even without a continuous power supply.

The flash memory device may receive a power voltage from an external source but may require a voltage higher than the power voltage and a high voltage switch to control the high voltage. However, over time, the high voltage switch undergoes threshold voltage degradation due to factors such as charge trapping, hot carrier injection, and bias temperature instability. As a result, the threshold voltage of the high voltage switch gradually increases, making it increasingly difficult for the high voltage switch to turn on when required. This may lead to programming and erasing failures, increased power consumption, memory malfunctions, and potential device failures in non-volatile memory systems.

### SUMMARY

According to an embodiment of the disclosure, a high voltage switch circuitry of a non-volatile memory device includes a first pass transistor (e.g., a PMOS) configured to transfer a driving voltage to an output terminal connected to a second pass transistor of the non-volatile memory device upon being turned on based on its gate receiving a negative voltage, a depletion mode transistor configured to provide the first pass transistor with the driving voltage based on an output signal fed back from the output terminal, a level shifter that applies a voltage to the gate of the first pass transistor, and a first voltage source that supplies the negative voltage less than a ground voltage to the level shifter. The level shifter applies the negative voltage from the first voltage source to the gate of the first pass transistor.

According to an embodiment of the disclosure, a high voltage switch circuitry of a non-volatile memory device include a pass transistor configured to transfer a driving voltage to an output terminal connected to a second pass transistor of the non-volatile memory device, a depletion mode transistor configured to provide a first source voltage to a source of the pass transistor in response to receiving a ground voltage at its gate, a level shifter configured to apply a voltage to the gate of the first pass transistor and a first voltage source configured to supply a negative voltage smaller than the ground voltage to the level shifter. In response to the pass transistor receiving the first source voltage and the application of the negative voltage to its gate, the pass transistor is configured to turn on and transfer a first positive voltage to the gate of the depletion mode transistor. A difference between the first source voltage and the negative voltage is greater than a threshold voltage of the pass transistor. The first voltage source is configured to supply the negative voltage to the level shifter for a predetermined time. The first transistor is configured to turn on at any point during the predetermined time. After the predetermined time, the first voltage source is further configured to supply the ground voltage to the level shifter.

According to an embodiment of the disclosure, a non-volatile memory device includes a memory cell array including memory cells connected to a word line, a voltage generator that generates a first high voltage, a first pass transistor that is connected to the word line, and a high voltage switch circuitry that the first high voltage to a second high voltage and provides the second high voltage to a gate of the first pass transistor. The high voltage switch circuitry includes a second pass transistor configured to transfer a driving voltage to an output terminal connected to the first pass transistor upon being turned on based on its gate receiving a negative voltage, a depletion mode transistor configured to provide the second pass transistor with the driving voltage based on an output signal fed back from the output terminal, a level shifter that applies a voltage to the gate of the second pass transistor, and a first voltage source that supplies the negative voltage less than a ground voltage to the level shifter. The level shifter applies the negative voltage from the first voltage source to the gate of the PMOS transistor.

According to an embodiment of the disclosure, a high voltage switch circuitry of a non-volatile memory device is provided. The high voltage switch circuitry includes a first pass transistor configured to transfer a driving voltage to an output terminal connected to a second pass transistor of the non-volatile memory device, upon being turned on based on its gate receiving a negative voltage. The circuitry further includes a depletion mode transistor configured to provide the first pass transistor with the driving voltage based on an output signal fed back from the output terminal, a level shifter configured to apply a voltage to the gate of the first pass transistor, and a first voltage source configured to selectively supply either a negative voltage smaller than a ground voltage or a ground voltage to the level shifter based on a current mode. When the current mode is an on mode, the first voltage source supplies the negative voltage to the level shifter, causing the level shifter to apply the negative voltage to the gate of the first pass transistor, thereby turning on the first pass transistor. When the current mode, is an off mode, the first voltage source supplies the ground voltage to the level shifter, preventing the first pass transistor from turning on.

### BRIEF DESCRIPTION OF THE DRAWINGS

The above and other objects and features of the present disclosure will become more apparent to those of ordinary skill in the art by describing in detail example aspects thereof with reference to the accompanying drawings, in which:

FIG. 1 is a block diagram illustrating a storage device according to an embodiment;

FIG. 2 is a block diagram illustrating a memory cell array in the non-volatile memory device of FIG. 1 according to an embodiment;

FIG. 3 is a circuit diagram illustrating one of the memory blocks of FIG. 2 according to an embodiment;

FIG. 4 is a block diagram illustrating a non-volatile memory device according to an embodiment;

FIG. 5 is a circuit diagram illustrating a structure of a row decoder according to an embodiment;

FIG. 6A is a circuit diagram illustrating the high voltage switch circuitry of FIG. 5 according to an embodiment;

FIG. 6B is a diagram schematically illustrating an input/output signal of the level shifter of FIG. 6A according to an embodiment;

FIG. 7A is a diagram illustrating a detailed structure of the level shifter of FIGS. 6A and 6B according to an embodiment;

FIG. 7B is a diagram provided to explain a process of supplying a ground voltage to the first voltage source of FIG. 7A according to an embodiment;

FIG. 8 is a diagram illustrating levels of signals transferred in off and on modes of the high voltage switch circuitry according to an embodiment;

FIG. 9A is a circuit diagram illustrating the high voltage switch circuitry of FIG. 5 according to an embodiment, and FIG. 9B is a diagram schematically illustrating input/output signals of the level shifter of FIG. 9A according to an embodiment;

FIG. 10A is a diagram illustrating a detailed structure of the level shifter of FIGS. 9A and 9B according to an embodiment;

FIG. 10B is a diagram provided to explain a process of supplying a ground voltage to the first voltage source of FIG. 10A according to an embodiment; and

FIG. 11 is a diagram illustrating levels of signals transferred in the off mode and on mode of the high voltage switch circuitry according to an embodiment.

### DETAILED DESCRIPTION

At least one embodiment of the present disclosure prevents or mitigates the degradation of the threshold voltage of a high-voltage pass transistor by implementing a voltage compensation mechanism that ensures the transistor continues to turn on reliably over time. This may be achieved by applying a precharge voltage to the depletion mode transistor, which increases the source voltage of the high-voltage pass transistor, ensuring that the voltage difference between the source and the gate remains greater than the threshold voltage even as the threshold voltage increases due to degradation. Additionally, a level shifter may supply a negative voltage to the gate of the high-voltage pass transistor rather than relying solely on the ground voltage, thereby compensating for the increased threshold voltage and ensuring that the transistor can still switch on properly despite prolonged use. As an additional benefit, this embodiment may reduce the circuit area of a row decoder for selecting and activating appropriate word lines in a memory array by removing unnecessary transistors in the high voltage switch circuitry, which increases integration density, lowers power consumption, and increases performance by reducing delay in word line voltage delivery.

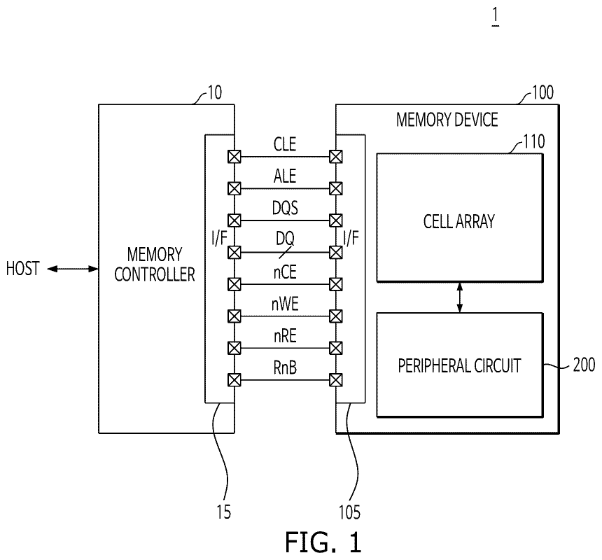

FIG. 1 is a block diagram illustrating a storage device. Referring to FIG. 1, a storage device 1 may include a memory controller 10 (e.g., a controller circuit) and a non-volatile memory device 100. The storage device 1 may store data in the memory device 100 under the control of the memory controller 10. For example, each of the memory controller 10 and the memory device 100 may be provided as one chip, one package, or one module. Alternatively, the memory controller 10 and the memory device 100 may be formed into one chip, one package, or one module, and provided as storage such as an embedded memory, a memory card, a memory stick, a solid state drive (SSD), etc.

The memory controller 10 may perform an access operation of writing data to the memory device 100 or reading data stored in the memory device 100 according to a request from a host. The memory controller 10 may generate a command CMD, an address ADDR, and a control signal CTRL for accessing the memory device 100.

The memory controller 10 may transmit the control signal CTRL to the memory device 100. A controller interface 15 of the memory controller 10 may be connected to a memory interface 105 of the memory device 100 through control pins and data pins. Control signals such as a command latch enable signal CLE, an address latch enable signal ALE, a data strobe signal DQS, a chip enable signal nCE, a read enable signal nRE, a write enable signal nWE and a ready/busy signal RnB may be transmitted from the memory controller 10 to the memory device 100 through the control pins.

The memory controller 10 and the memory device 100 may transmit and receive data signal DQ through the data pins. The memory controller 10 may transmit the command CMD, the address ADDR, and data DATA to the memory device 100 through the data signal DQ. The memory device 100 may identify (or capture) the data DATA provided through the data signal DQ based on a data strobe signal DQS. The memory device 100 may store the identified data DATA based on the received command CMD and address ADDR.

The memory device 100 may include a volatile or non-volatile memory such as a static RAM (SRAM), a dynamic RAM (DRAM), a synchronous DRAM (SDRAM), a read only memory (ROM), a programmable ROM (PROM), an electrically programmable ROM (EPROM), an electrically erasable and programmable ROM (EEPROM), a magnetic RAM (MRAM), a spin-transfer torque MRAM, a conductive bridging RAM (CBRAM), a ferroelectric RAM (FeRAM), a phase RAM (PRAM) or a resistive RAM.

The memory device 100 may include a memory cell array 110 and a peripheral circuit 200.

The memory cell array 110 may include memory cells connected to a word line and a bit line.

The memory cell array 110 may be positioned on a side surface or upper portion of the peripheral circuit 200 in terms of a design layout structure. A structure in which the memory cell array 110 is positioned above the peripheral circuit 200 may be referred to as a cell-on-peripheral (COP) structure. Meanwhile, the memory cell array 110 may be manufactured as a chip separate from the peripheral circuit 200. An upper chip including the memory cell array 110 and a lower chip including the peripheral circuit 200 may be connected to each other by a bonding method. This structure may be referred to as a chip to chip (C2C) structure.

The peripheral circuit 200 may include analog and/or digital circuits required to store data in the memory cell array 110 or to read or erase data stored in the memory cell array 110. The peripheral circuit 200 may receive external power from the memory controller 10 and generate internal power (e.g., Vcc) of various levels based on the external power.

The peripheral circuit 200 may store data in the memory cell array 110 under the control of the control signal CTRL. In addition, the peripheral circuit 200 may read data stored in the memory cell array 110 and provide the data to the memory controller 10 or erase the data stored in the memory cell array 110.

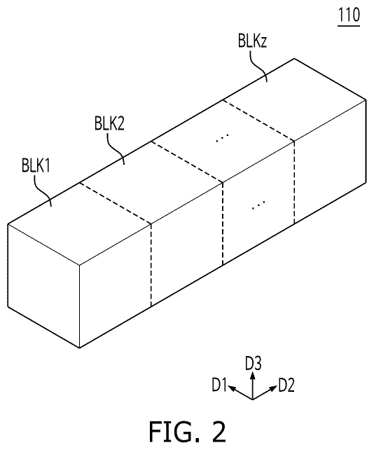

FIG. 2 is a block diagram illustrating a memory cell array in the non-volatile memory device of FIG. 1 according to an embodiment.

Referring to FIG. 2, the memory cell array 110 may include a plurality of memory blocks BLK1 to BLKz (where, z is a natural number greater than or equal to 2). The plurality of memory blocks BLK1 to BLKz may extend in first to third directions D1 to D3. The memory blocks BLK1 to BLKz may be selected by a row decoder (e.g., a decoder circuit) of the memory device (e.g., 100 of FIG. 1). For example, the row decoder may select a memory block corresponding to a block address from among the memory blocks BLK1 to BLKz.

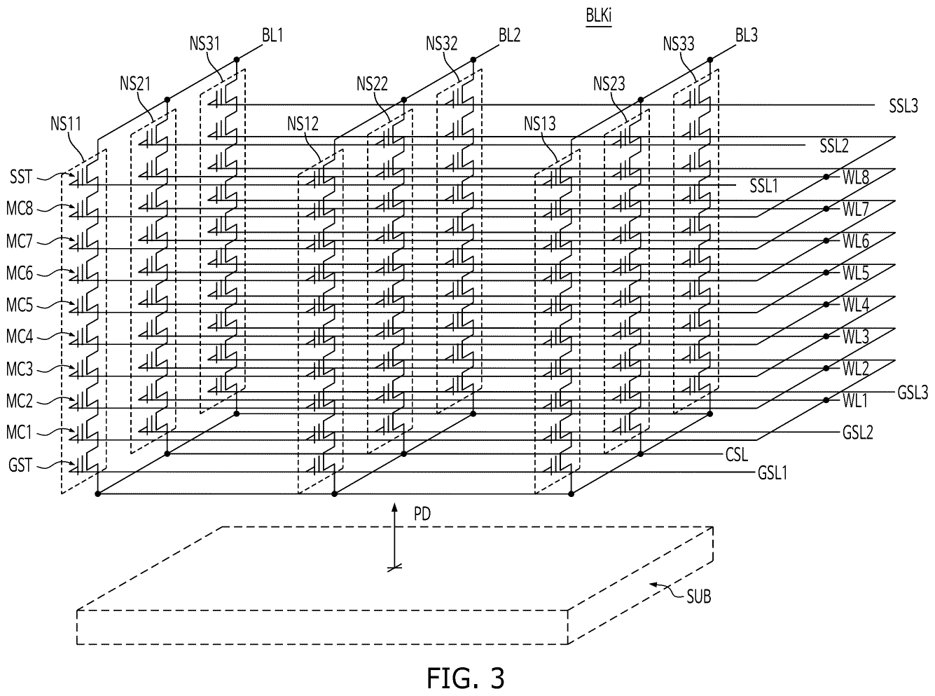

FIG. 3 is a circuit diagram illustrating one of the memory blocks of FIG. 2.

A memory block BLKi illustrated in FIG. 3 represents a three-dimensional memory block formed on a substrate SUB in a three-dimensional structure (where, i is a natural number greater than or equal to 1 and less than or equal to z in FIG. 2). For example, a plurality of memory cell strings included in the memory block BLKi may be stacked in a direction PD perpendicular to the substrate SUB.

Referring to FIG. 3, the memory block BLKi may include a plurality of memory cell strings NS11 to NS33 connected between bit lines BL1, BL2, and BL3 and a common source line CSL. Each of the plurality of memory cell strings NS11 to NS33 may include a string selection transistor SST, a plurality of memory cells MC1 to MC8, and a ground selection transistor GST.

The string selection transistor SST may be connected to corresponding string selection lines SSL1 to SSL3. The plurality of memory cells MC1 to MC8 may be connected to corresponding word lines WL1 to WL8, respectively. The ground selection transistor GST may be connected to corresponding ground selection lines GSL1 to GSL3. The string selection transistor SST may be connected to the corresponding bit lines BL1 to BL3, and the ground selection transistor GST may be connected to the common source line CSL.

The word lines (e.g., WL1) of the same height may be connected in common, and the ground selection lines GSL1 to GSL3 and the string selection lines SSL1 to SSL3 may be separated from each other.

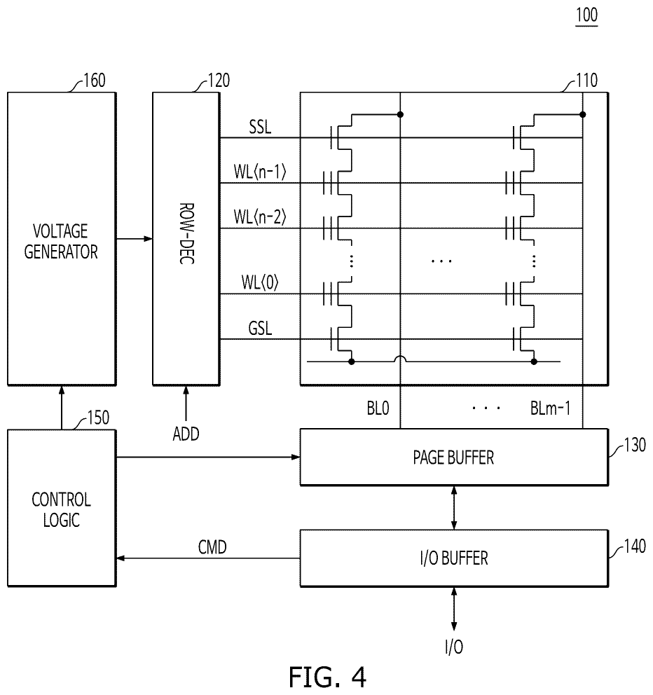

FIG. 4 is a block diagram illustrating a non-volatile memory device according to an embodiment. Referring to FIG. 4, the non-volatile memory device 100 may include the memory cell array 110, a row decoder 120, a page buffer 130, an input/output buffer 140, a control logic 150 (e.g., a logic circuit), and a voltage generator 160.

The memory cell array 110 may be connected to the row decoder 120 through the word lines WL<0> to WL<n-1> (where, n is a natural number greater than or equal to 2) or the selection lines SSL and GSL. The memory cell array 110 may be connected to the page buffer 130 through the bit lines BL0 to BLm-1 (where, m is a natural number greater than or equal to 2). The memory cell array 110 may include a plurality of NAND cell strings. Each of the cell strings may form a channel in a vertical or horizontal direction. The memory cells included in each of the cell strings may be programmed or erased by a high voltage provided from the row decoder 120.

The row decoder 120 may select any one of the memory blocks (e.g., BLK1 to BLKz in FIG. 2) of the memory cell array 110 in response to the row address ADD. The row decoder 120 may select one of the word lines WL<0> to WL<n-1> of the selected memory block.

The row decoder 120 may transfer the high voltage provided from the voltage generator 160 to the word lines or the selection lines SSL and GSL of the selected memory block.

The row decoder 120 may include a pass transistor including a high voltage transistor to transfer the high voltage to the selected memory block. That is, the pass transistor may transfer a high voltage generated by the voltage generator 160 to the memory block (or the word line) of the memory cell array 110. Because the pass transistor should be turned on or off by a high voltage, a high voltage switch circuitry may be required to boost a low voltage control signal to a high voltage in to switch the pass transistor.

The high voltage switch circuitry may convert the low voltage control signal to the level of external high voltage (e.g., Vpp) provided from the outside. For example, the high voltage switch circuitry may boost the level of an input signal (e.g., a control signal) to a boosted signal having a high voltage and provide a gate of the pass transistor with the boosted signal. As a result, the pass transistor including the high voltage transistor may be controlled by the high voltage switch circuitry by using the low voltage.

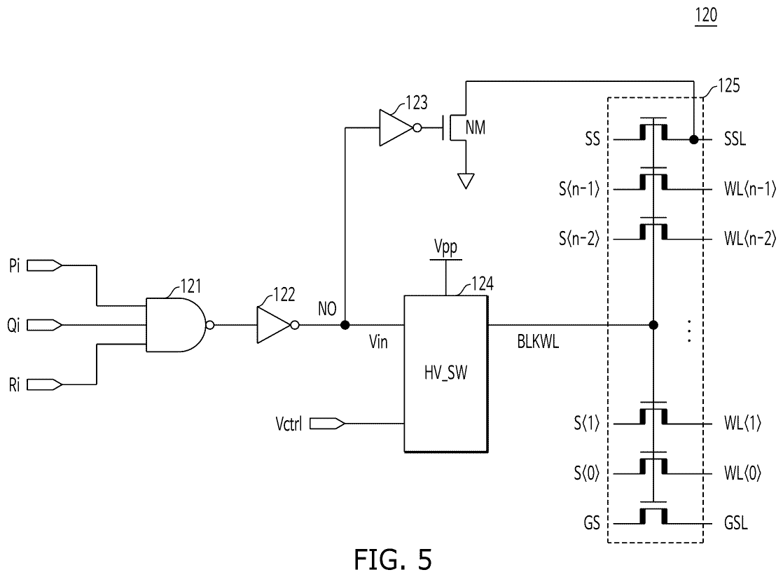

The high voltage switch circuitry may control a gate voltage of the pass transistor through a feedback structure using a depletion mode transistor and a P-channel Metal-Oxide-Semiconductor (PMOS) transistor. This will be described in detail below with reference to FIG. 5.

The page buffer 130 may operate as a write driver or a sense amplifier depending on an operation mode. During a program operation, the page buffer 130 may transfer a voltage corresponding to data to be programmed to the bit line of the memory cell array 110. During a read operation, the page buffer 130 may detect data stored in a selected memory cell through a bit line and transfer the data to the input/output buffer 140.

The input/output buffer 140 may transfer the input data to the page buffer 130 or output the data provided from the page buffer 130 to the outside. The input/output buffer 140 may transfer an input address ADD or a command CMD to the control logic 150 or the row decoder 120.

The control logic 150 may perform a control operation for executing a program operation, a read operation or an erase operation in response to the command CMD transferred from the input/output buffer 140. During the read operation, the control logic 150 may control the voltage generator 160 to generate a selection read voltage Vrd, a non-selection read voltage Vread, and selection line voltages VSSL and VGSL. In addition, the control logic 150 may control the page buffer 130 to detect data through the bit line.

The voltage generator 160 may generate various types of word line voltages to be supplied to each of the word lines WL<0> to WL<n-1> under the control of the control logic 150, and a voltage to be supplied to a bulk (e.g., a well region) in which memory cells are formed. The word line voltages to be supplied to each of the word lines WL<0> to WL<n-1> may include a program voltage, a pass voltage, selection voltages and non-selection read voltages. The voltage generator 160 may generate a selection line voltage to be provided to the selection lines SSL and GSL during the read operation and the program operation. The voltage generator 160 may provide a high voltage erase voltage to the bulk of the selected memory block during the erase operation.

The voltage generator 160 may use an external high voltage (e.g., Vpp) provided from the outside to generate a high voltage used for programming or erasing. This is because the boost speed and efficiency can be increased when the external high voltage is used.

FIG. 5 is a circuit diagram illustrating a structure of the row decoder according to an embodiment. Referring to FIG. 5, the row decoder 120 may include a NAND gate 121, inverters 122 and 123, a high voltage switch circuitry 124, and a pass transistor 125.

The NAND gate 121 and the inverter 122 may form a block decoder. The NAND gate 121 may perform a NAND logic operation on decoding signals Pi, Qi, and Ri provided by a row address. In addition, the output of the NAND gate 121 may be inverted by the inverter 122. Additionally, a configuration for blocking the output of the NAND gate 121 may be further provided depending on whether it corresponds to a bad block. For example, an AND gate or an OR gate can be used to block the output of the NAND gate 121 and prevent the selection of a bad memory block. In this approach, an AND gate is placed after the NAND gate 121, with one input receiving the output of the NAND gate 121 and the other input receiving a bad block flag signal. If the block is good, the AND gate passes the NAND gate 121 output as is, allowing the block to be selected. However, if the block is bad, the bad block flag is set to logic 0, forcing the AND gate output to logic 0, effectively blocking selection. Alternatively, an OR gate can be used, where the bad block flag is set to logic 1 for defective blocks, forcing the output high or low to prevent activation. The output of the inverter 122 may be transferred to a node N0 as a low-voltage block selection signal.

If all of the decoding signals Pi, Qi, and Ri are activated, the node N0 may be set to a high level. In addition, a switch NM for disabling the string selection line SSL may be turned off.

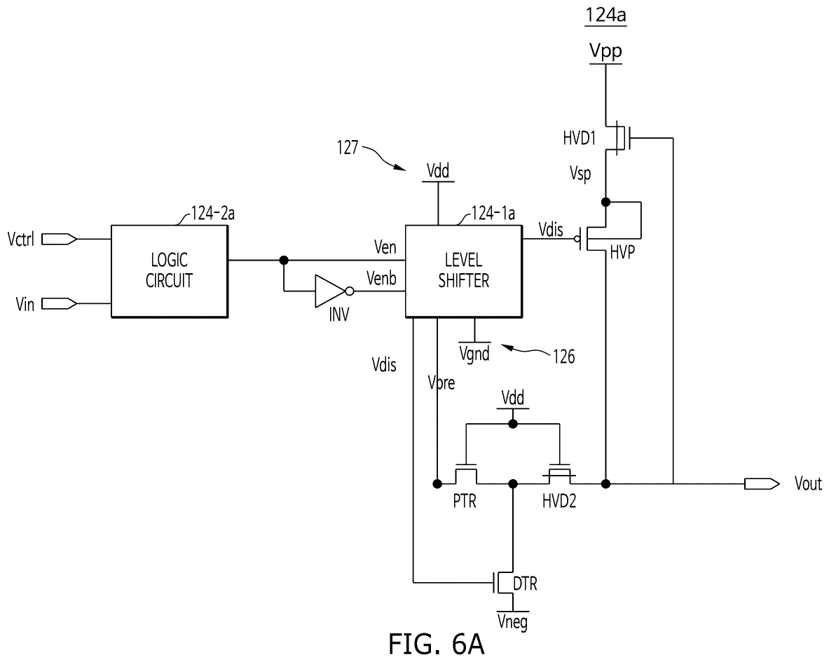

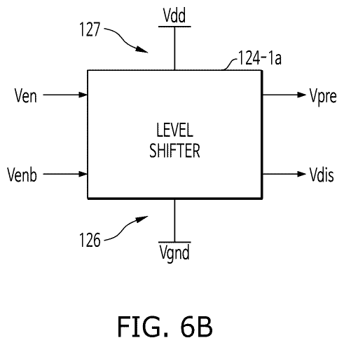

The high voltage switch circuitry 124 may receive a logic value of the node N0 and output a block selection signal boosted to a high voltage. The block selection signal changed to the high voltage level may be transferred to a block word line BLKWL. The pass transistor 125 may be switched by a high voltage block selection signal transferred to the block word line BLKWL. The high voltage switch circuitry 124 may use a feedback structure of a depletion mode transistor and a PMOS transistor to convert a low voltage block selection signal to a high voltage level. This will be described in detail below with reference to FIG. 6A.

As the pass transistor 125 is switched, voltages SS, GS, S<0> to S<i-1> generated by the voltage generator (e.g., 160 of FIG. 4) may be transferred to the word lines WL<0> to WL<n-1> or the selection lines SSL and GSL. For example, the pass transistor 125 may transfer the first high voltage generated by the voltage generator (e.g., 160 of FIG. 4) to the word line. The first high voltage may be a program voltage, a pass voltage, or an erase voltage for a selected memory block (e.g., any one of BLK to BLKz in FIG. 2) in the memory cell array (e.g., 110 in FIG. 4). The pass transistor 125 may transfer the first high voltage to the word line in response to the high voltage switch circuitry 124 boosting the level of the input signal to a second high voltage to generate a boosted signal and providing the boosted signal to the gate of the pass transistor 125.

The word line voltage transferred by the pass transistor 125 may be a relatively high voltage compared to a voltage for driving general circuits. Accordingly, the pass transistor 125 may be configured with a high voltage transistor driven at a high voltage.

FIG. 6A is a circuit diagram illustrating the high voltage switch circuitry of FIG. 5 according to an embodiment, and FIG. 6B is a diagram schematically illustrating the input/output signals of a level shifter 124-1a of FIG. 6A.

The high voltage switch circuitry 124a of FIG. 6A may illustrate an aspect of the high voltage switch circuitry 124 of FIG. 5. Referring to FIG. 6A, the high voltage switch circuitry 124a may include the level shifter 124-1a, a logic circuit 124-2a, an inverter INV, depletion mode transistors HVD1 and HVD2, a PMOS transistor HVP (e.g., a high-voltage transistor), a precharge transistor PTR, and a discharge transistor DTR. In an embodiment, the depletion mode transistors HVD1 and HVD2 are NMOS transistors but are not limited thereto. A driving voltage provided from the outside may be provided as a power supply voltage of the logic circuit 124-2a and the inverter INV, and may be different from a first driving voltage Vdd supplied from a second voltage source 127 of the level shifter 124-1a. A second driving voltage Vpp, which is a high voltage, may be applied to a first depletion mode transistor HVD1.

The logic circuit 124-2a may be configured as a logic circuit. The logic circuit 124-2a may receive an input signal Vin and a control signal Vctrl. The input signal Vin and the control signal Vctrl may correspond to the input signal Vin and the control signal Vctrl of FIG. 5, respectively. The logic circuit 124-2a may generate an enable signal Ven based on the received input signal Vin and control signal Vctrl. When the input signal Vin is at a high level, the high voltage switch circuitry 124a may be turned on. In addition, when the input signal Vin is at a low level, the high voltage switch circuitry 124a may be turned off.

Referring to FIGS. 6A and 6B, the level shifter 124-1a may receive the enable signal Ven and an inverted enable signal Venb. The inverted enable signal Venb may be provided by inverting the enable signal Ven by the inverter INV. In response to the enable signal Ven and the inverted enable signal Venb, the level shifter 124-1a may transfer a discharge voltage Vdis to each of a gate of the discharge transistor DTR and a gate of the PMOS transistor HVP and may transfer a precharge voltage Vpre to a source of the precharge transistor PTR.

The discharge voltage Vdis transferred from the level shifter 124-1a to the gate of the discharge transistor DTR and the gate of the PMOS transistor HVP may be a voltage supplied from one of a first voltage source 126 or the second voltage source 127 to the level shifter 124-1a and transferred from the level shifter 124-1a. The precharge voltage Vpre supplied to the source of the precharge transistor PTR may be a voltage supplied from the other one of the first voltage source 126 or the second voltage source 127 to the level shifter 124-1a and transferred from the level shifter 124-1a. For example, the level shifter 124-1a may dynamically select between two voltage sources 126 and 127 to supply the discharge voltage Vdis and the precharge voltage Vpre for proper transistor operation. The discharge voltage Vdis, applied to the gates of the discharge transistor DTR and the PMOS transistor HVP, may be sourced from either the first or second voltage source. Whichever voltage source is not used for Vdis supplies the precharge voltage Vpre to the source of the precharge transistor PTR.

In one example, a ground voltage Vgnd supplied from the first voltage source 126 is transferred to the gate of the discharge transistor DTR and the gate of the PMOS transistor HVP as the discharge voltage Vdis, and the first driving voltage Vdd supplied from the second voltage source 127 is applied to the source of the precharge transistor PTR as the precharge voltage Vpre. In this case, since the ground voltage Vgnd is applied to the gate of the discharge transistor DTR, the discharge transistor DTR is not turned on, and thus a negative voltage Vneg is not transferred from the source of the discharge transistor DTR to a second depletion mode transistor HVD2. Through the second depletion mode transistor HVD2, which is turned on by the application of the first driving voltage Vdd to its gate, the first driving voltage Vdd applied to the source of the precharge transistor PTR may be transferred to a gate of the first depletion mode transistor HVD1. For example, the second depletion mode transistor HVD2 is turned on by the first driving voltage Vdd, allowing Vdd to pass through and be applied to the gate of the first depletion mode transistor HVD1. Accordingly, in response to a source voltage Vsp of the PMOS transistor HVP increasing and a difference between the source voltage and the gate voltage of the PMOS transistor HVP exceeding a threshold voltage, the PMOS transistor HVP may be turned on. For example, when the source voltage Vsp of the PMOS transistor HVP increases, the voltage difference between the source and gate becomes larger. Once this difference exceeds the threshold voltage of HVP, the transistor turns on, allowing current to flow and enabling high-voltage switching.

In another example, the ground voltage Vgnd supplied from the first voltage source 126 may be transferred to the source of the precharge transistor PTR as the precharge voltage Vpre, and the first driving voltage Vdd supplied from the second voltage source 127 may be transferred to the gate of the discharge transistor DTR and the gate of the PMOS transistor HVP as the discharge voltage Vdis. The ground voltage Vgnd applied to the source of the precharge transistor PTR may be transferred to the gate of the first depletion mode transistor HVD1 through the second depletion mode transistor HVD2 turned on by the first driving voltage Vdd. Since the first driving voltage Vdd is applied to the gate of the discharge transistor DTR, the discharge transistor DTR may be turned on, and the negative voltage Vneg may be transferred from the source of the discharge transistor DTR to the gate of the first depletion mode transistor HVD1. Since the first driving voltage Vdd is applied to the gate of the PMOS transistor HVP, the difference between the source voltage and the gate voltage of the PMOS transistor HVP may be less than the threshold voltage, and thus the PMOS transistor HVP should not be turned on.

The first depletion mode transistor HVD1 and the PMOS transistor HVP may form a feedback structure to provide an output signal Vout from an output terminal. For example, if a block of the non-volatile memory device (e.g., 100 in FIG. 4) is selected for a program, a read, or an erase operation, the second driving voltage Vpp may be provided to a drain of the first depletion mode transistor HVD1, and the high voltage switch circuitry 124a may transfer an externally provided second driving voltage Vpp to the pass transistor (e.g., 125 in FIG. 5).

Specifically, if the block of the non-volatile memory device 100 is selected, the discharge voltage Vdis may be transferred to the gate of the PMOS transistor HVP as the ground voltage Vgnd by the level shifter 124-1a. As a result, in response to the difference between the source voltage and the gate voltage (the ground voltage Vgnd) of the PMOS transistor HVP exceeding the threshold voltage, the PMOS transistor HVP may be turned on. Since the output signal Vout is initially at the ground voltage Vgnd, the gate voltage of the first depletion mode transistor HVD1 may be provided as the ground voltage Vgnd. The PMOS source voltage Vsp may then be increased up to a threshold voltage Vth of the first depletion mode transistor HVD1. For example, the source voltage Vsp of the PMOS transistor HVP may increase until it reaches the threshold voltage Vth of the first depletion mode transistor HVD1. Therefore, the output signal Vout may be the threshold voltage Vth of the first depletion mode transistor HVD1. The output signal Vout may be fed back to the gate of the first depletion mode transistor HVD1. In response, the PMOS source voltage Vsp may increase to a value Vdd+Vth obtained by summing the output signal Vout and the threshold voltage Vth of the first depletion mode transistor HVD1. For example, the source voltage Vsp of the PMOS transistor HVP may increase to a value equal to the sum of the first driving voltage Vdd and the threshold voltage Vth of the first depletion mode transistor HVD1. As the process described above repeats, the output signal Vout may increase up to the second driving voltage Vpp. As a result, the second driving voltage Vpp may be finally provided to the pass transistor 125. This means that through repeated iterations of the positive feedback loop involving the PMOS transistor and the depletion mode transistor HVD1, the output voltage gradually increases. Each cycle of the process boosts the output signal a bit more until it eventually reaches the predetermined high voltage level (e.g., the second driving voltage, Vpp) required to properly drive the pass transistor 125 during memory operations.

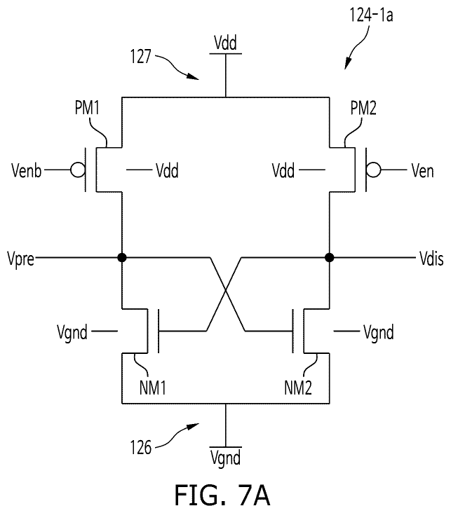

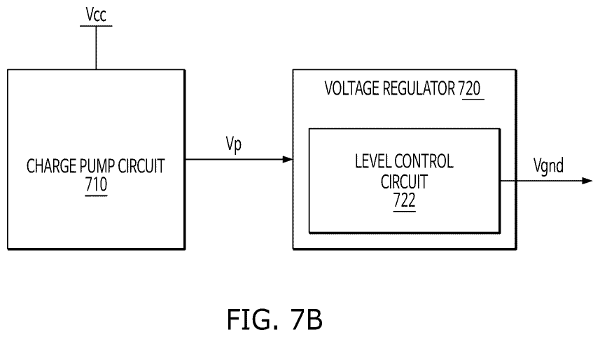

FIG. 7A is a diagram illustrating a detailed structure of the level shifter 124-1a of FIGS. 6A and 6B according to an embodiment.

The level shifter 124-1a may include a first PMOS transistor PM1 for pull-up driving of the precharge signal Vpre in response to the inverted enable signal Venb, a second PMOS transistor PM2 for pull-up driving of the discharge signal Vdis in response to the enable signal Ven, a first NMOS transistor NM1 for driving the precharge signal Vpre to the level of the ground voltage Vgnd in response to the discharge signal Vdis, and a second NMOS transistor NM2 for driving the discharge signal Vdis to the level of the ground voltage Vgnd in response to the precharge signal Vpre.

In one example, in response to the enable signal Ven being at a high level and the inverted enable signal Venb being at a low level, the discharge voltage Vdis may be output as the ground voltage Vgnd, and the precharge voltage Vpre may be output as the first driving voltage Vdd. That is, the level shifter 124-1a may provide the voltage received from the first voltage source 126 to the gate of the PMOS transistor HVP of FIG. 6A. For example, when the enable signal Ven is high and its inverted signal Venb is low, the discharge voltage Vdis is pulled down to ground Vgnd, while the precharge voltage (Vpre) is raised to the first driving voltage Vdd.

Alternatively, in response to the enable signal Ven being at a low level and the inverted enable signal Venb being at a high level, the discharge voltage Vdis may be output as the first driving voltage Vdd, and the precharge voltage Vpre may be output as the ground voltage Vgnd. That is, a level shifter 124-1b may provide the voltage received from the second voltage source 127 to the gate of the PMOS transistor HVP of FIG. 6A. For example, when the enable signal Ven is low and its inverted signal Venb is high, the discharge voltage Vdis is raised to the first driving voltage Vdd, while the precharge voltage Vpre is pulled down to ground Vgnd.

FIG. 7B is a diagram provided to explain a process of supplying the ground voltage Vgnd to the first voltage source 126 of FIG. 7A according to an embodiment.

A charge pump circuit 710 and a voltage regulator 720 may be included in the memory device (e.g., 100 of FIG. 4). For example, the charge pump circuit 710 and the voltage regulator 720 may be included in the voltage generator of the memory device (e.g., 160 of FIG. 4).

The charge pump circuit 710 may be enabled or disabled by a control circuit, and may perform a charge pumping operation using the power supply voltage Vcc to output a pumping voltage Vp.

The voltage regulator 720 may regulate the pumping voltage Vp output from the charge pump circuit 710 to generate a voltage. Specifically, the voltage regulator 720 may include a level control circuit 722, and the level control circuit 722 may control the level of voltage generated with the pumping voltage Vp to provide the ground voltage Vgnd to the first voltage source 126 of the level shifter 124-1a of FIG. 7A.

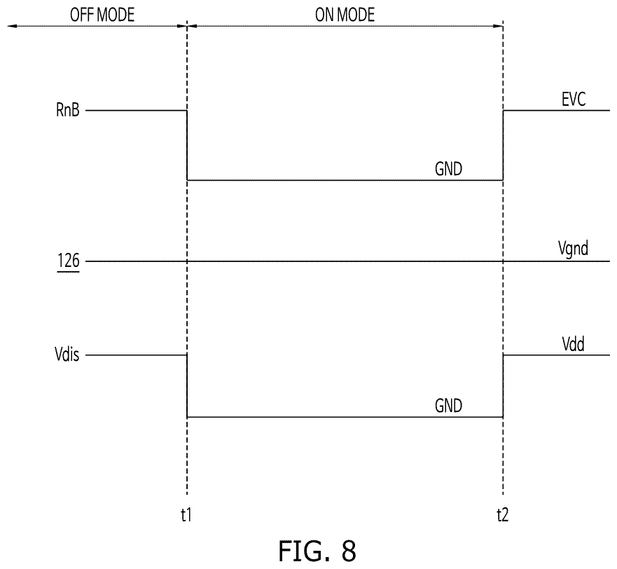

FIG. 8 is a diagram illustrating levels of signals transferred in off and on modes of the high voltage switch circuitry according to an embodiment.

The high voltage switch circuitry may be in the off mode state while the ready/busy signal RnB (e.g., RnB in FIG. 1) is maintained at the level of the external voltage EVC. The high voltage switch circuitry may be in the on mode state during the interval between a first time t1 and a second time t2 in which the ready/busy signal RnB is maintained at the level of the ground voltage GND. For example, the high-voltage switch circuitry remains off when the ready/busy signal RnB is at an external voltage EVC, indicating an idle state. It turns on between times t1 and t2 when RnB is at ground voltage GND, signaling an active high-voltage operation such as programming or erasing in the memory device.

Referring to FIGS. 6A and 8, while the voltage supplied from the first voltage source 126 is maintained at the ground voltage GND, with the high voltage switch circuitry in the off mode, the discharge voltage Vdis may be maintained at the level of the first driving voltage Vdd by the level shifter 124-1a, and with the high voltage switch circuitry in the on mode, the discharge voltage Vdis may be maintained at the level of the ground voltage GND supplied from the first voltage source 126. With the high voltage switch circuitry in the on mode, the ground voltage GND may be transferred to the gate of the PMOS transistor HVP as the discharge voltage Vdis such that the PMOS transistor HVP may be turned on, and the second driving voltage Vpp may be transferred as the output signal Vout by the positive feedback process described above with reference to FIG. 6A.

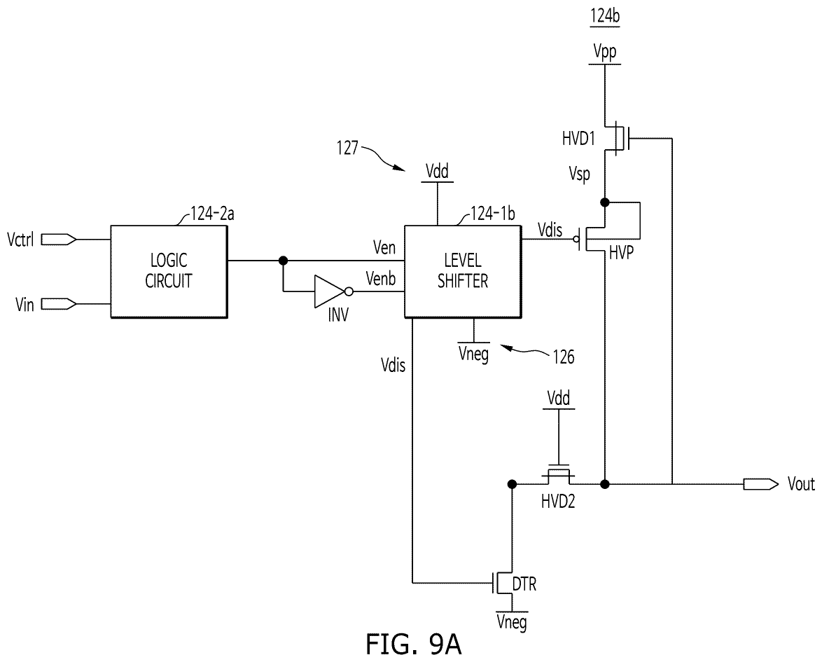

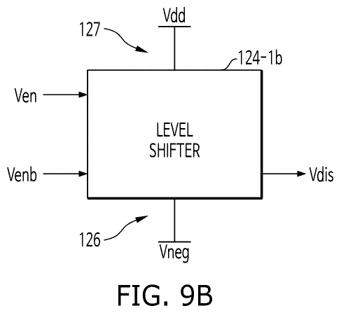

FIG. 9A is a circuit diagram illustrating the high voltage switch circuitry of FIG. 5 according to an embodiment, and FIG. 9B is a diagram schematically illustrating input/output signals of the level shifter 124-1b of FIG. 9A according to an embodiment.

The high voltage switch circuitry 124b of FIG. 9A may illustrate an aspect of the high voltage switch circuitry 124 of FIG. 5. The high voltage switch circuitry 124b of FIG. 9A may be the high voltage switch circuitry 124a of FIG. 6A from which the precharge transistor PTR is removed or omitted. Accordingly, the area occupied by the high voltage switch circuitry 124b or the row decoder including the high voltage switch circuitry 124b may be reduced, and the integration density of the non-volatile memory device may be increased. In addition, power consumption required for driving the precharge transistor PTR may be reduced, so that a power-efficient memory system may be implemented. For the high voltage switch circuitry 124b of FIG. 9A, descriptions of the same configurations and operations as those of the high voltage switch circuitry 124a of FIG. 6A may be omitted.

The logic circuit 124-2a may generate the enable signal Ven based on the input signal Vin and the control signal Vctrl, and may transfer the generated enable signal Ven to the level shifter 124-1b. The inverter INV may receive the enable signal Ven from the logic circuit 124-2a to generate the inverted enable signal Venb, and transfer the generated inverted enable signal Venb to the level shifter 124-1b.

Based on the enable signal Ven and the inverted enable signal Venb, the level shifter 124-1b may provide the gate of the PMOS transistor HVP with the voltage received from the first voltage source 126 or the voltage received from the second voltage source 127. In response to the enable signal at a high level and the inverted enable signal at a low level, the level shifter 124-1b may provide the gate of the PMOS transistor HVP with the voltage received from the first voltage source 126. In response to the enable signal at a low level and the inverted enable signal at a high level, the level shifter 124-1b may provide the gate of the PMOS transistor HVP with the voltage received from the second voltage source 127. For example, when the enable signal is low and the inverted enable signal is high, the level shifter 124-1b provides the gate of the PMOS transistor HVP with a voltage from the second voltage source 127.

As described above with reference to FIG. 6A, to provide the second driving voltage Vpp to the pass transistor 125, it is necessary to perform a positive feedback process in which the PMOS transistor HVP is turned on and the output signal Vout rises to the second driving voltage Vpp. For example, since the output signal Vout is initially at the ground voltage Vgnd, the ground voltage Vgnd may be applied to the gate of the first depletion mode transistor HVD1. In response to the application of the ground voltage Vgnd to the gate of the first depletion mode transistor HVD1, the first depletion mode transistor HVD1 may transfer a first source voltage corresponding to a difference between the threshold voltage and the ground voltage of the first depletion mode transistor HVD1 to the source of the PMOS transistor HVP. The PMOS transistor HVP may receive the first source voltage, turn on, and transfer the first positive voltage to the gate of the depletion mode transistor HVD1. In response to receiving the first positive voltage, the first depletion mode transistor HVD1 may transfer the second source voltage to the source of the PMOS transistor HVP, and in response to receiving the second source voltage, the PMOS transistor HVP may transfer the second positive voltage to the gate of the first depletion mode transistor HVD1. In this case, the second source voltage may be greater than the first source voltage, and the second positive voltage may be greater than the first positive voltage. As the process described above repeats, the output signal Vout may increase up to the second driving voltage Vpp. That is, in response to the PMOS transistor HVP turning on, a positive feedback process may be initiated and the output signal Vout may rise to the second driving voltage Vpp. For example, as the positive feedback process repeats, the output signal Vout gradually increases with each cycle until it reaches the final second driving voltage Vpp, ensuring the high-voltage switch is fully activated for memory operations.

For the PMOS transistor HVP to turn on, the difference between the source voltage and the gate voltage of the PMOS transistor HVP should be greater than the threshold voltage of the PMOS transistor HVP. Meanwhile, the threshold voltage of the PMOS transistor HVP may increase over the initial threshold voltage as the PMOS transistor HVP deteriorates. For example, it is assumed that the first source voltage is greater than the initial threshold voltage and less (or smaller) than the threshold voltage after deterioration. In this case, if a ground voltage is applied to the gate of the PMOS transistor HVP before the deterioration of the PMOS transistor HVP, the difference between the first source voltage and the ground voltage may be greater than the initial threshold voltage, allowing the PMOS transistor HVP to turn on. However, under the above assumption, the difference between the first source voltage and the ground voltage may be less (or smaller) than the threshold voltage after the deterioration of the PMOS transistor HVP, in which case the PMOS transistor HVP may not be turned on.

To address this issue, the level shifter 124-1a in FIG. 6A may apply the first driving voltage Vdd as the precharge voltage Vpre. This application of Vpre causes the gate voltage of the first depletion mode transistor HVD1 to increase. As a result, the source voltage Vsp of the PMOS transistor HVP also increases. By raising Vsp, the circuit ensures that the PMOS transistor HVP can still turn on, even if its threshold voltage has increased due to deterioration over time.

In the high voltage switch circuitry 124b of FIG. 9A, the first voltage source 126 may supply the negative voltage Vneg (e.g., a voltage level lower than the ground voltage) to the level shifter 124-1b. This negative voltage Vneg helps ensure that the PMOS transistor HVP can still turn on, even if its threshold voltage has increased due to deterioration over time. That is, in response to the application of the negative voltage Vneg to the gate of the PMOS transistor HVP, the difference between the first source voltage and the gate voltage of the PMOS transistor HVP may increase to be greater than the threshold voltage of the PMOS transistor HVP, thus allowing the PMOS transistor HVP to turn on. If the threshold voltage of the PMOS transistor HVP is greater than the difference between the first source voltage and the ground voltage, the first voltage source 126 may supply the negative voltage Vneg to the level shifter 124-1b.

In response to the level shifter 124-1b providing the gate of the PMOS transistor HVP with the voltage received from the second voltage source 127, the PMOS transistor may be turned off.

Referring to FIGS. 9A and 9B, the precharge transistor PTR of FIG. 6A may be removed or omitted from the high voltage switch circuitry 124b of FIG. 9A, in which case a circuit for connecting the level shifter 124-1b and the precharge transistor PTR may also be removed or omitted.

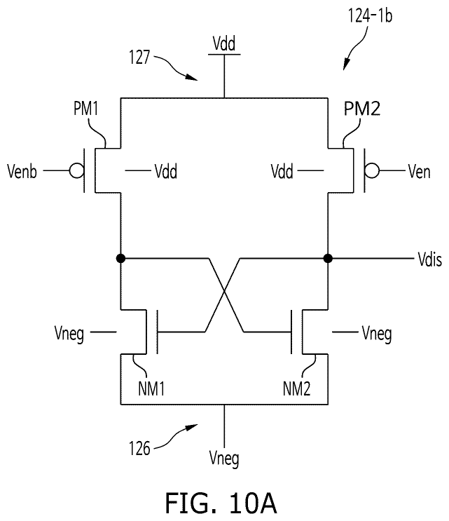

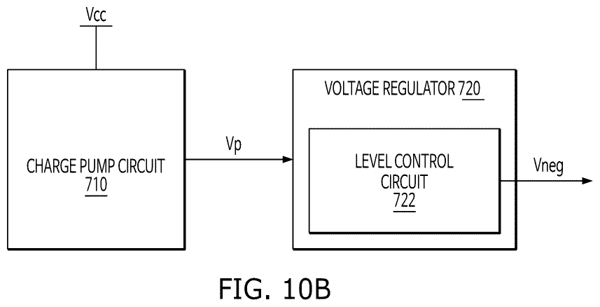

FIG. 10A illustrates a detailed structure of the level shifter 124-1b of FIGS. 9A and 9B according to an embodiment, and FIG. 10B is a diagram provided to explain a process of supplying the ground voltage Vneg to the first voltage source 126 of FIG. 10A according to an embodiment.

The level shifter 124-1b of FIG. 10A will be described below, while redundant descriptions of the same configurations and operations as those of the level shifter 124-1a of FIG. 7A already described above may be omitted. Referring to FIGS. 7A and 10A, the level shifter 124-1b in FIG. 10A differs from the level shifter 124-1a in FIG. 7A, in that the circuitry for connecting the precharge transistor PTR has been removed or omitted.

The charge pump circuit 710 and the voltage regulator 720 of FIG. 10B will be described below, while redundant descriptions of the same configurations and operations as those of the charge pump circuit 710 and the voltage regulator 720 of FIG. 7B already described above may be omitted. Referring to FIGS. 10A and 10B, the charge pump circuit 710 and the voltage regulator 720 may transfer the negative voltage Vneg less than the ground voltage to the first voltage source 126 of the level shifter 124-1a.

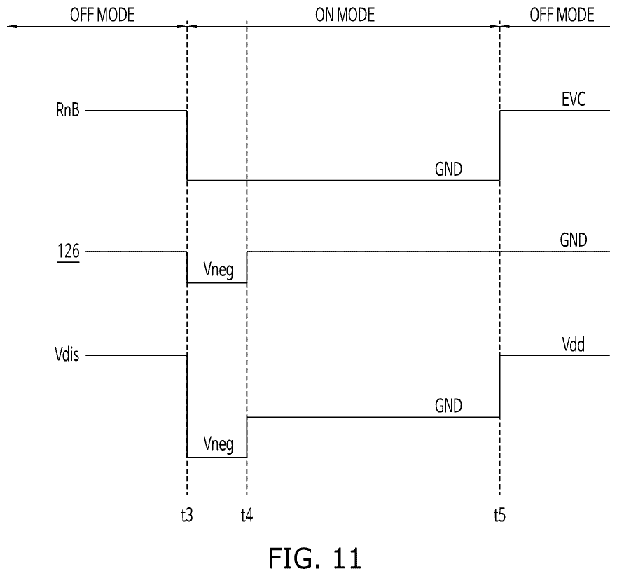

Additionally, the voltage regulator 720 may transfer the ground voltage to the first voltage source 126. That is, through this, the first voltage source 126 may transfer the ground voltage or the negative voltage less than the ground voltage to the level shifter 124-1b. This will be described in detail below with reference to FIG. 11.

FIG. 11 is a diagram illustrating levels of signals transferred in off and on modes of the high voltage switch circuitry according to an embodiment.

The high voltage switch circuitry may be in the off mode state while the ready/busy signal RnB (e.g., RnB in FIG. 1) is maintained at the level of the external voltage EVC. Between a third time t3 and a fifth time t5 in which the ready/busy signal RnB is maintained at the level of the ground voltage GND, the high voltage switch circuitry may be in the on mode state.

Referring to FIGS. 9A and 11, if the voltage supplied from the first voltage source 126 is maintained at the ground voltage GND, the difference between the source voltage and the gate voltage of the PMOS transistor HVP may be less than the threshold voltage of the PMOS transistor HVP and accordingly, the high voltage switch circuitry may be in the off mode. In the off mode, the discharge voltage Vdis may be maintained at the level of the first driving voltage Vdd by the level shifter 124-1a.

To switch the high voltage switch circuitry to the on mode, the negative voltage Vneg may be applied from the first voltage source 126 to the gate of the PMOS transistor HVP (e.g., a pass transistor) at the third time t3. In the on mode, the discharge voltage Vdis may be transferred to the gate of the PMOS transistor HVP as the negative voltage Vneg, causing the difference between the source voltage and the gate voltage of the PMOS transistor HVP to be greater than the threshold voltage of the PMOS transistor HVP, thereby allowing the PMOS transistor HVP to turn on and the second driving voltage Vpp to be transferred as the output signal Vout by the positive feedback. In an embodiment, the first pass transistor turns on when the voltage difference between its source and gate exceeds its threshold voltage. Specifically, the first source voltage applied to the source of the first pass transistor increases, while the negative voltage applied to its gate decreases, ensuring that the source-gate voltage difference remains greater than the threshold voltage required for turn-on.

The first voltage source 126 may supply the negative voltage Vneg to the level shifter for a predetermined time. For example, the first voltage source 126 of FIG. 11 may supply the negative voltage Vneg to the level shifter between the third time t3 and a fourth time t4. The PMOS transistor HVP may be turned on at a certain time point (i.e., a certain time point of a predetermined time) between the third time t3 and the fourth time t4. The first voltage source 126 may supply the ground voltage GND to the level shifter after the predetermined time. Referring to FIG. 9A, the first voltage source 126 may supply the negative voltage Vneg to the level shifter only for a predetermined time. This controlled timing prevents deterioration of the second depletion mode transistor HVD2 that may occur when a high voltage difference is maintained for an extended period. Specifically, when the negative voltage Vneg (e.g., about −1V) is applied to the drain of the second depletion mode transistor HVD2 due to the discharge transistor DTR, and the second driving voltage Vpp (e.g., about +29V) is applied elsewhere in the circuit, prolonged exposure to this large voltage difference could accelerate transistor degradation.

The present disclosure is not limited to the aspects described above and the accompanying drawings, and various forms of substitution, modification, and change are possible by those of ordinary skill in the art without departing from the technical idea of the present disclosure described in the claims, which also fall within the scope of the present disclosure.

What is claimed is:

1. A high voltage switch circuitry of a non-volatile memory device, comprising:
a first pass transistor configured to transfer a driving voltage to an output terminal connected to a second pass transistor of the non-volatile memory device, upon being turned on based on its gate receiving a negative voltage;
a depletion mode transistor configured to provide the first pass transistor with the driving voltage based on an output signal fed back from the output terminal;
a level shifter configured to apply a voltage to the gate of the first pass transistor; and
a first voltage source configured to supply the negative voltage smaller than a ground voltage to the level shifter,
wherein the level shifter is further configured to apply the negative voltage from the first voltage source to the gate of the first pass transistor.

2. The high voltage switch circuitry according to claim 1, wherein,
in response to the ground voltage being applied to a gate of the depletion mode transistor, the depletion mode transistor is configured to transfer a first source voltage corresponding to a difference between a threshold voltage of the depletion mode transistor and the ground voltage to a source of the first pass transistor, and
in response to the first pass transistor receiving the first source voltage and the negative voltage, the first pass transistor is turned on and transfers a first positive voltage to the gate of the depletion mode transistor.

3. The high voltage switch circuitry according to claim 2, wherein,
in response to receiving the first positive voltage, the depletion mode transistor is configured to transfer a second source voltage to the source of the first pass transistor,
in response to receiving the second source voltage, the first pass transistor is configured to transfer a second positive voltage to the gate of the depletion mode transistor,
the second source voltage is greater than the first source voltage, and
the second positive voltage is greater than the first positive voltage.

4. The high voltage switch circuitry according to claim 2, wherein a difference between the first source voltage and the negative voltage is greater than a threshold voltage of the first pass transistor.

5. The high voltage switch circuitry according to claim 2,
wherein the first voltage source is configured to supply the negative voltage to the level shifter for a predetermined time, and
wherein the first pass transistor is turned on at any point during the predetermined time.

6. The high voltage switch circuitry according to claim 5, wherein the first voltage source is further configured to supply the ground voltage to the level shifter after the predetermined time.

7. The high voltage switch circuitry according to claim 2,
wherein a first threshold voltage of the first pass transistor is greater than an initial threshold voltage of the first pass transistor, and
wherein the first source voltage is greater than the initial threshold voltage and less than the first threshold voltage.

8. The high voltage switch circuitry according to claim 7, wherein, if a threshold voltage of the first pass transistor is greater than the difference between the first source voltage and the ground voltage, the first voltage source is configured to supply the negative voltage to the level shifter.

9. The high voltage switch circuitry according to claim 2, wherein the difference between the first source voltage and the ground voltage is less than a threshold voltage of the first pass transistor.

10. The high voltage switch circuitry according to claim 1, further comprising a second voltage source configured to supply a power supply voltage to the level shifter, wherein
the level shifter is configured to provide the gate of the first pass transistor with the voltage received from the first voltage source or the voltage received from the second voltage source, based on an enable signal and an inverted enable signal.

11. The high voltage switch circuitry according to claim 10, wherein, in response to the enable signal at a high level and the inverted enable signal at a low level, the level shifter is configured to provide the gate of the first pass transistor with the voltage received from the first voltage source.

12. The high voltage switch circuitry according to claim 10, wherein, in response to the enable signal at a low level and the inverted enable signal at a high level, the level shifter is configured to provide the gate of the first pass transistor with the voltage received from the second voltage source.

13. The high voltage switch circuitry according to claim 12, wherein, in response to the level shifter providing the gate of the first pass transistor with the voltage received from the second voltage source, the first pass transistor is turned off.

14. The high voltage switch circuitry according to claim 10, further comprising
a logic circuit configured to generate the enable signal based on an input signal and a control signal and transfer the generated enable signal to the level shifter.

15. The high voltage switch circuitry according to claim 14, further comprising an inverter configured to receive the enable signal from the logic circuit, generate the inverted enable signal, and transfer the generated inverted enable signal to the level shifter.

16. A high voltage switch circuitry of a non-volatile memory device, comprising:
a pass transistor configured to transfer a driving voltage to an output terminal upon being turned;
a depletion mode transistor configured to provide a first source voltage to a source of the pass transistor in response to receiving a ground voltage at its gate;
a level shifter configured to apply a voltage to the gate of the first pass transistor; and
a first voltage source configured to supply a negative voltage smaller than the ground voltage to the level shifter,
wherein in response to the pass transistor receiving the first source voltage and the negative voltage to its gate, the pass transistor is configured to turn on and transfer a first positive voltage to the gate of the depletion mode transistor,
wherein a difference between the first source voltage and the negative voltage is greater than a threshold voltage of the pass transistor,
wherein the first voltage source is configured to supply the negative voltage to the level shifter for a predetermined time,
wherein the first transistor is configured to turn on at any point during the predetermined time, and
wherein after the predetermined time, the first voltage source is further configured to supply the ground voltage to the level shifter.

17. A non-volatile memory device, comprising:
a memory cell array comprising memory cells connected to a word line;
a voltage generator configured to generate a first high voltage;
a first pass transistor connected to the word line; and
a high voltage switch circuitry configured to boost the first high voltage to a second high voltage and provide the second high voltage to a gate of the first pass transistor, wherein
the high voltage switch circuitry comprises:
a second pass transistor configured to transfer a driving voltage to an output terminal connected to the first pass transistor, upon being turned on based on its gate receiving a negative voltage;
a depletion mode transistor configured to provide the second pass transistor with the driving voltage based on an output signal fed back from the output terminal;
a level shifter configured to apply a voltage to the gate of the second pass transistor; and
a first voltage source configured to supply the negative voltage smaller than a ground voltage to the level shifter,
wherein the level shifter is further configured to apply the negative voltage supplied from the first voltage source to the gate of the second pass transistor.

18. The non-volatile memory device according to claim 17, wherein
a difference between the first source voltage and the negative voltage is greater than a threshold voltage of the second pass transistor, and
a difference between the first source voltage and the ground voltage is less than the threshold voltage.

19. The non-volatile memory device according to claim 17, wherein, in response to the high voltage switch circuitry providing the gate of the first pass transistor with the second high voltage, the first pass transistor is configured to transfer the first high voltage to the word line.

20. The non-volatile memory device according to claim 17, wherein the first high voltage is a program voltage, a pass voltage, or an erase voltage for a selected memory block in the memory cell array.
